(19) United States
(12) Patent Application Publication
(10) Pub. No.: US 2025/0369095 A1
(43) Pub. Date: Dec. 4, 2025

(54) SYSTEM AND METHOD FOR APPLICATION OF ELECTRO-OPTICAL FILM STACKS ON SUBSTRATES WITHOUT BREAKING VACUUM

(71) Applicant: CORNING INCORPORATED, CORNING, NY (US)

(72) Inventors: ChaHyun Ku, Gumi-si (KR); Robert George Manley, Ithaca, NY (US); Jeonghong Oh, Cheonan-si (KR); Sang-Yoon Oh, Cheonan City (KR); Sung-kun Yoon, Yeoju-si (KR); Jung-Hun Yun, Asan city (KR)

(21) Appl. No.: 19/223,643

(22) Filed: May 30, 2025

Related U.S. Application Data
(60) Provisional application No. 63/653,361, filed on May 30, 2024.

(51) Int. Cl. C23C 14/50; C03C 17/36; C23C 14/14; C23C 14/34; C23C 14/54; G02B 1/11

(52) U.S. Cl. CPC C23C 14/505; C03C 17/3657; C03C 17/3668; C23C 14/14; C23C 14/34; C23C 14/541; G02B 1/11; C03C 2218/154

(57) ABSTRACT

A system for depositing coatings on a plurality of substrates is disclosed. The system includes a first chamber with first deposition modules configured to deposit nonconductive coatings on the plurality of substrates. A first rotating drum is configured to hold the plurality of substrates, within the first chamber. A second chamber includes a plurality of second deposition modules configured to deposit conductive coatings on the plurality of substrates. A second rotating drum is configured to hold the plurality of substrates within the second chamber. A transfer chamber is disposed between the first chamber and the second chamber. The first chamber, the transfer chamber, and the second chamber are connected in such a manner that the plurality of substrates can be transferred back and forth from the first chamber through the transfer chamber to the second chamber without breaking vacuum.

### CROSS REFERENCE TO RELATED APPLICATION

This application claims the benefit of priority under 35 U.S.C. § 119 of U.S. Provisional Application Ser. No. 63/653,361 filed on May 30, 2024, the content of which is relied upon and incorporated herein by reference in its entirety their entireties.

### BACKGROUND

The disclosure relates to a system and method for producing a glass article having optical and electrical coatings and, more particularly, to system and method of applying such coatings to a glass substrate without breaking vacuum when transitioning between an optical coating deposition chamber and an electrical coating deposition chamber.

In modern electronics, glass articles are required to fulfill increasingly complex requirements in terms of optical performance. Additionally, incorporation of sensors and temperature control requires that the glass articles include electrical coatings as well. Such electrical coatings, though, should not diminish or degrade the desired properties of the optical coatings. However, the optical coatings generally are nonconductive and composed of different materials than the conductive electrical coatings, thereby requiring different deposition parameters. For this reason, optical coatings are deposited in a chamber that is separate from the chamber for deposition of electrical coatings. Notwithstanding, each coating is preferably deposited under vacuum to prevent contamination of the coating. In conventional systems, transportation of the glass article between optical and electrical deposition chambers requires vacuum to be broken, introducing a source of contamination between layers of the coating stack.

### SUMMARY

According to an aspect, embodiments of the disclosure relate to a system for depositing coatings on a plurality of substrates. The system includes a first chamber comprising a plurality of first deposition modules arranged around a first perimeter of the first chamber. The plurality of first deposition modules is configured to deposit nonconductive coatings on the plurality of substrates. The first perimeter of the first chamber defines a first interior. A first rotating drum is configured to hold the plurality of substrates, and the first rotating drum is disposed in the first interior. The system further includes a second chamber comprising a plurality of second deposition modules arranged around a second perimeter of the second chamber. The second deposition modules are configured to deposit conductive coatings on the plurality of substrates. The second perimeter of the second chamber defines a second interior. A second rotating drum is configured to hold the plurality of substrates, and the second rotating drum is disposed in the second interior. A transfer chamber is disposed between the first chamber and the second chamber. The transfer chamber comprises at least one transfer robot configured to transfer substrates between the first rotating drum and the second rotating drum. The first chamber, the transfer chamber, and the second chamber are connected in such a manner that the plurality of substrates can be transferred back and forth from the first chamber through the transfer chamber to the second chamber without breaking vacuum.

According to another aspect, embodiments of the disclosure relate to a method of applying coatings to a plurality of substrate batches. In the method, a first substrate batch is loaded onto a first rotating drum that is configured to rotate within a first chamber. A first coating is deposited under vacuum on the first substrate batch using a plurality of first deposition modules. The first coating is one of a nonconductive optical coating or a conductive electrical coating. The first substrate batch is transferred from the first chamber through a transfer chamber into a second chamber. The first substrate batch is loaded onto a second rotating drum that is configured to rotate within the second chamber. A second coating is deposited under vacuum on the first substrate batch, using a plurality of second deposition modules. The second coating is the other of the nonconductive optical coating or the conductive electrical coating. The first coating and the second coating are deposited without breaking vacuum during transferring from the first chamber through the transfer chamber and into the second chamber.

According to still another aspect, embodiments of the disclosure relate to a glass article. The glass article includes a glass substrate and a stack of coatings disposed on the glass substrate. The stack of coatings comprises at least one nonconductive optical coating and at least one conductive electrical coating. At each interface between the at least one nonconductive optical coating and the at least one conductive electrical coating, contamination of the at least one nonconductive optical coating and of the at least one conductive electrical coating is less than 1000 ppm.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIGS. 1-3 are profile views of a glass article including an electro-optical coating stack on a glass substrate, according to exemplary embodiments.

FIG. 4 depicts a system for depositing an electro-optical coating stack on a glass substrate without breaking vacuum, according to an exemplary embodiment.

FIG. 5 is a process flow diagram of a method for parallel processing of batches of glass substrates as the batches are moved back-and-forth between optical and electrical coating deposition chambers without breaking vacuum, according to an exemplary embodiment.

FIGS. 6A and 6B depict portions of a frame of a rotating drum configured to hold glass substrates during deposition of conductive electrical coatings, according to an exemplary embodiment.

FIG. 7 depicts a stack of plates to provide electrical biasing and thermal regulation of the glass substrates during deposition as well as a clamping mechanism to hold the glass substrates, according to an exemplary embodiment.

FIG. 8 depicts an alternative interlocking arrangement between a carrier and bias plate for holding the carrier during deposition, according to an exemplary embodiment.

FIG. 9 depicts a glass substrate held to a carrier using double-sided tape according to an exemplary embodiment.

FIG. 10 depicts an expansion clamp for holding non-planar glass substrates to a carrier, according to an exemplary embodiment.

FIG. 11 depicts a first example of a recessed clamp for holding a glass substrate to a carrier, according to an exemplary embodiment.

FIGS. 12 and 13 depict a second example of a recessed clamp for holding a glass substrate to a carrier, according to an exemplary embodiment.

### DETAILED DESCRIPTION

Reference will now be made in detail to various embodiments of a system and method for forming a glass article having an electro-optical coating stack disposed on a glass substrate, examples of which are illustrated in the accompanying drawings. As will be discussed more fully below, certain glass articles now desirably include both optical and electrical coatings. Such coatings are typically applied through various physical vapor deposition processes, but the optical coatings have different compositions and deposition requirements than the electrical coatings. As such, these types of coatings should be deposited in different chambers so that the coatings do not cross-contaminate each other. However, transporting the substrates between chambers for application of the optical and electrical coatings can cause contamination of the coated surface, leading the final glass article to be contaminated between the layers. According to the present disclosure, a system and method are provided in which glass substrates are transported between optical and electrical deposition chambers without breaking vacuum, significantly reducing or eliminating contamination between layers of the electro-optical stack. These and other aspects and advantages of the disclosed system and method for forming glass articles with electro-optical coating stacks on a glass substrate will be described in relation to the embodiments provided below and in the drawings. These embodiments are presented by way of example and not by way of limitation.

Light detection and ranging (LiDAR) applications utilize a laser to scan an environment and collect reflections back from the environment, typically for the purposes of identifying objects in the environment. For example, self-driving vehicles may utilize LiDAR to navigate a roadway and avoid pedestrians or other obstacles in the roadway. The laser is shone through a window, which is put in place to protect the internal components of the LiDAR sensor. Because of the light passing back-and-forth through window, it is desirable that the window not unnecessarily distort the outgoing or incoming optical signal. For this reason, the window is often provided with optical coatings, such as an antireflective coating. Further, for outdoor applications, there may be a need to defrost or defog the window, and thus, it is desirable to include an electrically conductive coating to carry current, e.g., to a resistive heating element. As mentioned above, though, providing such combined electro-optical coatings is difficult because of the issues associated with contamination between layers of the electro-optical coating stack. The glass article produced according to the method of the present disclosure using the system of the present disclosure addresses these problems. The LiDAR application mentioned herein is merely to illustrate one context in which optical and electrical coatings may both be desired on a glass article; however, the present disclosure is not limited to LiDAR applications.

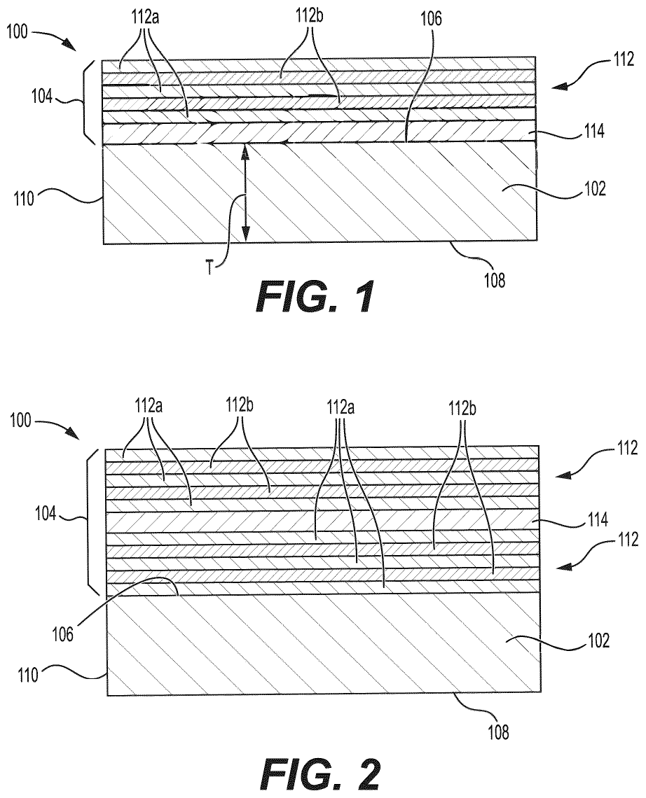

FIG. 1 depicts an example embodiment of a glass article 100 including a glass substrate 102 and an electro-optical stack 104. The glass substrate 102 includes a first major surface 106 and a second major surface 108 opposite to the first major surface 106. The first major surface 106 and the second major surface 108 define a thickness T of the glass substrate 102. In one or more embodiments, the thickness T is in a range from 0.1 mm to 10 mm, in particular in a range from 0.5 mm to 3 mm. A minor surface 110 extends around a perimeter of the glass substrate 102 and connects the first major surface 106 to the second major surface 108.

The electro-optical stack 104 is disposed on the first major surface 106, the second major surface 108, or both the first major surface 106 and the second major surface 108. The electro-optical stack 104 includes at least one nonconductive optical coating 112 and at least one conductive electrical coating 114. In one or more embodiments, the nonconductive optical coating 112 has an electrical conductivity of 10⁻⁶ S/cm or less, and/or the nonconductive optical coating 112 has an electrical resistivity of at least 10⁶ Ωcm, in particular at least 10¹³ Ωcm. In one or more embodiments, the nonconductive optical coating 112 is selected from a group comprising an index matching coating, an antireflective coating, a band-pass filter, a scratch-resistant coating, a decorative coating, or combinations thereof. In one or more embodiments, the nonconductive optical coating 112 comprises a ceramic selected from the group consisting of oxides, nitrides, oxynitrides, or fluorides of silicon, titanium, niobium, vanadium, iron, aluminum, zirconium, hafnium, chromium, tungsten, magnesium, calcium, and combinations thereof. For example, in one or more embodiments, the nonconductive optical coating 112 comprises one or more of SiO₂, SiN, AIO, AlN, SiON, AlON, MgF₂, or CaF₂. In one or more embodiments, each layer of the nonconductive optical coating 112 has a thickness in a range of 0.001 μm (1 nm) to 5 μm (5000 nm), in particular in a range of 0.005 μm (5 nm) to 0.250 μm (250 nm).

In one or more embodiments, the conductive electrical coating 114 has an electrical conductivity of at least 10 S/cm, in particular at least 104 S/cm, and/or the conductive electrical coating 114 has an electrical resistivity of 10³ Ωcm or less, in particular 10⁻³ Ωcm or less. In one or more embodiments, the conductive electrical coating 114 is a transparent conductive oxide, a metal film, or conductive carbon (e.g., graphene or carbon nanotubes). In one or more embodiments, the conductive electrical coating 114 comprises a material selected from the group consisting of indium oxide, tin oxide, indium tin oxide, indium gallium zinc oxide, indium gallium tin oxide, indium tungsten oxide, aluminum zinc oxide, zinc oxide, copper (II) oxide (CuO), zinc sulfide doped with copper and/or aluminum, doped silicon, silver, indium, tin, zinc, copper, silicon, conductive carbon, and combinations thereof. In one or more embodiments, each layer of the conductive electrical coating 114 has a thickness in a range of 0.010 μm (10 nm) to 2 μm (2000 nm), in particular in a range of 0.025 μm (25 nm) to 0.200 μm (200 nm).

The nonconductive optical coating 112 and conductive electrical coating 114 can be located substantially anywhere in the electro-optical stack 104. However, in general, the conductive electrical coating 114 is disposed within the electro-optical stack 104 and not on an exterior of the electro-optical stack 104 where it may accidentally come into contact with other conductive materials. In the embodiment shown in FIG. 1, the conductive electrical coating 114 is disposed on and in contact with the first major surface 106 of the glass substrate 102. Further, as shown in FIG. 1, the electro-optical stack 104 can include more than one nonconductive optical coating 112, such as a first nonconductive optical coating 112a (e.g., antireflective coating) and a second nonconductive optical coating 112b (e.g., index matching coating). In the embodiment shown in FIG. 1, the first and second nonconductive optical coatings 112a, 112b are alternatingly stacked on the conductive electrical coating 114.

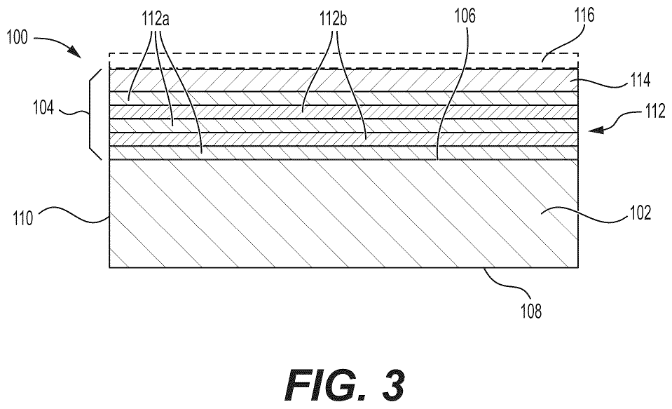

FIG. 2 depicts another embodiment of the glass article 100 in which the conductive electrical coating 114 is disposed in the middle of the electro-optical stack 104. That is, a nonconductive optical coating 112 is disposed on and in contact with the first major surface 106. The electro-optical stack 104 includes alternating first and second nonconductive optical coatings 112a, 112b, followed by a conductive electrical coating 114, and further followed by alternating first and second nonconductive optical coatings 112a, 112b.

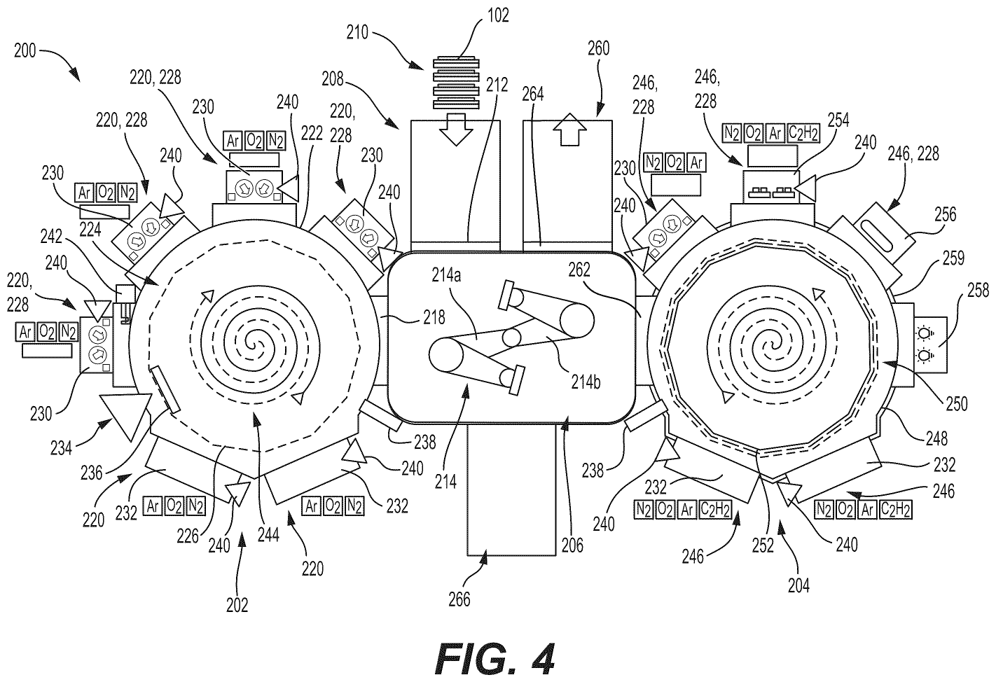

FIG. 3 depicts a further embodiment of the glass article 100 in which the conductive electrical coating 114 is disposed at the top of the electro-optical stack 104 (i.e., disposed on the side of the electro-optical stack 104 opposite to the first major surface 106). As mentioned above, having the conductive electrical coating 114 disposed on the exterior of the stack may lead to unintentional electrical contact with the surroundings, and therefore, as shown in FIG. 3, the conductive electrical coating 114 is shown with an optional nonconductive coating 116, such as SiO₂, SiN, or a polymer coating (e.g., benzocyclobutene). Further, the nonconductive coating 116 may be the same as one of the first or second nonconductive coating 112a, 112b, or the nonconductive coating 116 may be a different electrically insulating coating.

As will be discussed more fully below, the presently disclosed electro-optical stack 104 is prepared by successively applying the conductive electrical coating 114 and the nonconductive optical coating 112 without breaking vacuum. Advantageously, maintaining vacuum while applying the different optical and electrical coatings 112, 114 avoids contamination and impurities from forming between the coating layers 112, 114. In one or more embodiments, at each interface between the at least one nonconductive optical coating 112 and the at least one conductive electrical coating 114, contamination of the at least one nonconductive optical coating 112 and of the at least one conductive electrical 114 coating by foreign contaminants, undesirable coating phases, and/or material from the adjacent coating layer is less than 1000 ppm, in particular less than 100 ppm, as measured, for example, using mass spectroscopy or energy dispersive X-ray spectroscopy. Notwithstanding and as will be discussed more fully below, the coatings are 112, 114 are applied in separate chambers to prevent the conductive electrical coating 114 from contaminating the nonconductive optical coating 112, and vice versa. In particular, conductive coatings provide free and mobile electrons to allow for current flow, but desirably, the nonconductive optical coatings do not contain materials providing mobile electrons because such mobility can diminish the optical properties of the coating, giving the optical coating a dark or dirty appearance.

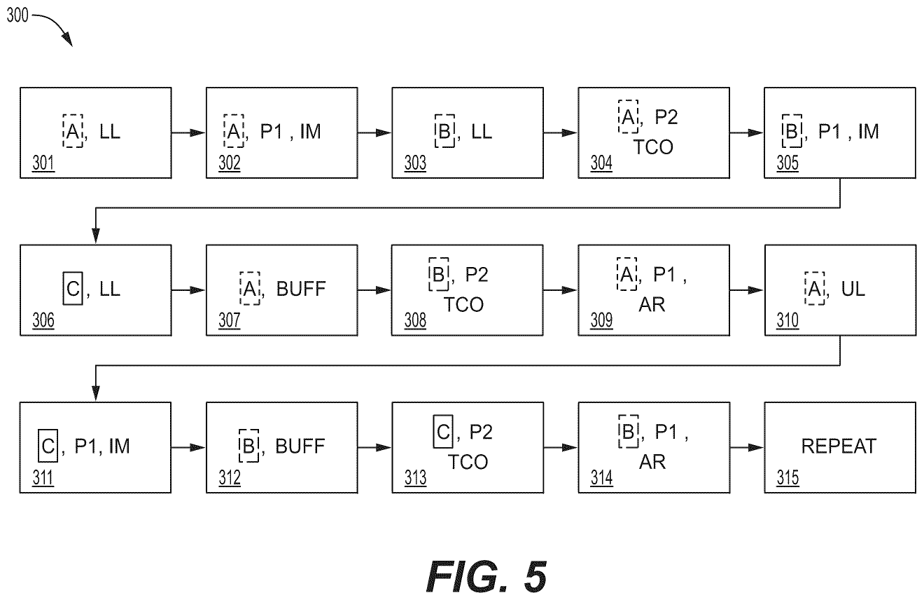

The glass article 100 is prepared using a system 200 as shown in FIG. 4. As can be seen, the system 200 includes a first chamber 202 and a second chamber 204 connected by a transfer chamber 206. As can be seen in FIG. 4, substrates 102 are loaded into the system through a load lock 208. In particular, the load lock 208 is configured to receive a plurality of substrates 102 for transport into the transfer chamber 206. In one or more embodiments, the substrates 102 are provided on cassettes 210 that facilitate loading and holding of the substrates 102 in the load lock 208. In one or more embodiments, the load lock 208 is isolated from the transfer chamber 206 by a first valve 212, such as a gate valve (also referred to as a slot valve), for reasons that will be explained more fully below.

Disposed within the transfer chamber 206 is at least one transfer robot 214, shown as first transfer robot 214a and second transfer robot 214b in FIG. 4. The at least one transfer robot 214 picks the cassettes 210 or the substrates 102 from the cassettes 210 for transfer into the first chamber 202. In one or more embodiments, the first chamber 202 is isolated from the transfer chamber 206 by a second valve 218, such as a gate valve.

The first chamber 202 comprises a plurality of first deposition modules 220 arranged around a first perimeter 222 of the first chamber 202. The plurality of first deposition modules 220 are configured to deposit nonconductive optical coatings 112 on the plurality of substrates 102 (e.g., as shown in FIGS. 1-3). The first perimeter 222 of the first chamber 202 defines a first interior 224. A first rotating drum 226 configured to hold the plurality of substrates 102 is disposed in the first interior 224. The first rotating drum 226 rotates within the first chamber 202 so as to expose the substrates 102 carried on the rotating drum to the first plurality of deposition modules 220.

In one or more embodiments, the plurality of first deposition modules 220 comprises sputtering modules 228 configured to deposit metal ions on the plurality of substrates 102. In one or more embodiments, the sputtering modules 228 comprise dual rotary magnetron (DRM) sputtering modules 230. Advantageously, DRM sputtering modules 230 provide a high rate of deposition and utilize a higher amount of target material than other types of sputtering modules. Notwithstanding, other types of sputtering modules 228 may be used, such as planar sputtering modules, which use targets that are less expensive and easier to manufacture, or hollow cathode sputtering modules, which provide higher density coating films but are also expensive by comparison. In one or more embodiments, the first deposition chamber 202 further comprises at least one high density inductively coupled plasma (HDICP) module 232 configured cause a reaction between the metal ions and at least one of oxygen or nitrogen.

In one or more embodiments, the first chamber 202 may include other monitoring or control elements. As shown in FIG. 4, the first chamber 202 includes an optical monitoring system (OMS) 234, which provides the ability to monitor optical thin film properties in real time during deposition by measuring the optical thickness of individual layers, thereby allowing for adjustment to the layer thickness during deposition. The OMS 234 can monitor the thickness directly on the substrate 102 or indirectly on a witness substrate 236 as shown in FIG. 4. FIG. 4 also depicts a residual gas analyzer (RGA) 238 for monitoring the process environment before, during, and after sputtering. In each of the sputtering and HDICP modules 228, 232, an optical emission spectrometer (OES) 240 is provided to monitor the plasma condition. Still further, FIG. 4 depicts a laser particle counter 242, which analyzes the concentration of particles in the air for quality monitoring.

In one or more embodiments, the first rotating drum 226 is configured to be electrically biased to facilitate deposition of the optical coating onto the substrates 102. Biasing the rotating drum 226 during deposition may lead to improved adhesion, density, and crystallinity, to decreased surface roughness, and to increased film thickness of the nonconductive optical coating 112, depending on the particular material of the coating. In one or more embodiments, the first rotating drum 226 is biased at a DC voltage of up to 1000 V, in particular in a range of about 50 V to about 200 V. In one or more embodiments, the DC voltage bias is pulsed.

In one or more embodiments, the first chamber 202 further includes a polycold cryochiller 244 on the interior walls or bottom wall of the first chamber 202. A polycold cryochiller 244 is a refrigerant system that is configured to capture water vapor and other condensable substances within a vacuum to improve the time to create a vacuum as well as the quality thereof.

After applying the nonconductive optical coating 112 in the first chamber 202, the at least one transfer robot 214 picks the substrates 102 (or a carrier thereof) from the first rotating drum 226. The transfer robot 214 then transfers the substrates 102 to the second chamber 204 for application of a conductive electrical coating 114.

In some ways, the second chamber 204 is similar to the first chamber 202. Namely, the second chamber 204 comprises a plurality of second deposition modules 246 arranged around a second perimeter 248 of the second chamber 204. However, the second deposition modules 246 are configured to deposit conductive electrical coatings 114 on the plurality of substrates 102 (e.g., directly on the substrate 102 or onto a previously applied nonconductive optical coating 112). The second perimeter 248 of the second chamber 204 defines a second interior 250. A second rotating drum 252 configured to hold the plurality of substrates 102 is disposed in the second interior 250.

In one or more embodiments, the plurality of second deposition modules 246 comprises sputtering modules 228 configured to deposit metal ions on the plurality of substrates 102. In one or more embodiments, the sputtering modules 228 comprise at least one of a DRM sputtering module 230, a high-power impulse magnetron sputtering (HiPIMS) module 254, or a linear ion source module 256. The DRM sputtering module 230 provides the advantages discussed above. The HiPIMS module 254 can enhance the density of the coating films applied, and the linear ion source module 256 can polish the conductive electrical coating film layers to make the coatings smoother. In general, it is desirable that the conductive coatings have high density to enhance conductivity, but conductive electrical coatings also tend to be rougher than optical nonconductive coatings. Thus, the combination of sputtering modules 228 described can provide both dense and smooth conductive electrical coatings. In one or more embodiments, the second deposition chamber 204 further comprises at least one HDICP module 232 configured cause a reaction between the metal ions and at least one of oxygen, nitrogen, or acetylene. In one or more embodiments, the second deposition chamber 204 further comprises a heating module 258. In one or more embodiments, the heating module 258 is configured to anneal the conductive electrical coating 114 as it is applied, which also enhances the density and smoothness of the conductive electrical coating 114. Further, in one or more embodiments, the heating module 258 may alternatively or additionally provide general temperature control during processing. Additional temperature control can be provided by a thermal management unit 259 provided around the perimeter of the second chamber 204. For example, the thermal management unit 259 may be a water-cooling jacket and/or resistive heating wrap to cool or warm the second chamber 204 as desired.

As shown in FIG. 4, the second chamber 204 may include any or all of the monitoring or control elements discussed in relation to the first chamber 202, such as an optical monitoring system (OMS) 234 (including witness chip 236), a residual gas analyzer (RGA) 238, an optical emission spectrometer (OES) 240, and/or a laser particle counter 242.

In one or more embodiments, the second rotating drum 252 is configured to be DC biased, e.g., at a voltage up to 1000 V, in particular in a range from about 50 V to about 200 V. Further, in one or more embodiments, the second rotating drum 252 includes a temperature regulation system configured to heat or cool the glass substrates 102 during deposition. For example, the temperature regulation system may carry a refrigerant configured to heat or cool the glass substrates 102. In embodiments in which the second rotating drum 252 is configured for electrical biasing and for temperature regulation, the temperature regulation system is electrically isolated from the biasing system. A structure of the second rotating drum 252 configured to provide biasing, temperature regulation, and electrical isolation is described more fully below.

After the conductive electrical coating 114 is deposited onto the substrates 102, the at least one transfer robot 214 picks the substrates from the second rotating drum 252. If all of nonconductive optical coatings 112 and conductive electrical coatings 114 have been applied, then the at least one transfer robot 214 ejects the substrates through an unload lock 260. However, if additional nonconductive optical coatings 112 are required, then the at least one transfer robot 214 transfers the glass substrates from the second chamber 204 through the transfer chamber 206 back to the first chamber 202.

As mentioned above, the load lock 208 is isolated from the transfer chamber 206 by a first valve 212, and the first chamber is isolated from the transfer chamber 206 by a second valve 218. Similarly, the second chamber 204 is isolated from the transfer chamber 206 by a third valve 262, such as a gate valve, and the unload lock 260 is isolated from the transfer chamber 206 by a fourth valve 264, such as a gate valve. In this way, when substrates are loaded into the transfer chamber 206 through the load lock 208, the first valve 212 and the fourth valve 264 can be closed and vacuum drawn in the first chamber 202, the second chamber 204, and the transfer chamber 206. In this way, substrates 102 can be passed back and forth between the first chamber 202 and the second chamber 204 without breaking vacuum so as to build the electro-optical stack 104.

While the foregoing discussion was framed in terms of one batch of substrates 102 being passed back and forth between the first chamber 202 and the second chamber 204 to build up the electro-optical stack 104, the system 200 can be used to process two or three batches of substrates 102 in parallel. For example, after a first batch of substrates 102 is positioned on the first rotating drum 226 of the first chamber 202, a second batch of substrates 102 can be positioned on the second rotating drum 252 in the second chamber 204. In this way, a nonconductive optical coating 112 can be applied at the same time as a conductive electrical coating 114 on different batches of substrates 102. During such parallel depositions, the second valve 218 and the third valve 262 may be closed to prevent cross-contamination of the coatings.

Additionally, while the second valve 218 and the third valve 262 are closed, a third batch of substrates 102 can be loaded into the transfer chamber 206 through the load lock 208. Upon receiving the third batch of substrates 102 into the transfer chamber 206, the first valve 212 and the fourth valve 264 can be closed so that a vacuum can be drawn in the transfer chamber 206. While the first and second batches of substrates 102 have their respective coatings deposited, the third batch of substrates 102 can be held in a buffer chamber 266. Thus, for example, if a first batch of substrates is receiving a nonconductive optical coating 112 in the first chamber 202 and a second batch of substrates is receiving a conductive electrical coating 114 in the second chamber 204 and if the application of the conductive electrical coating 114 takes less time than application of the nonconductive optical coating 112, then the third batch of substrates 102 can be loaded into the second chamber 204 while the second batch of substrates is unloaded from the second chamber 204 and into the buffer chamber 266. Accordingly, down time in the system 200 is minimized, and vacuum is maintained on the coated or semi-coated substrates 102 throughout the coating process.

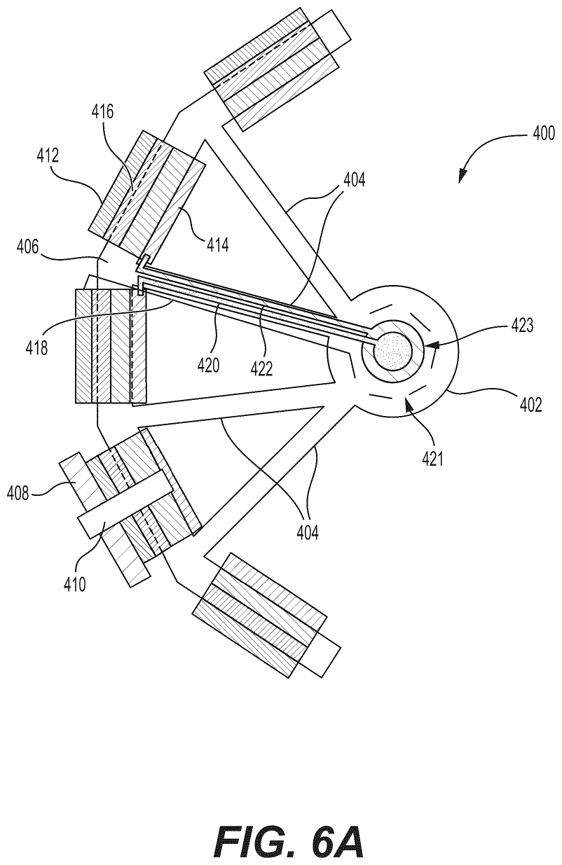

FIG. 5 provides a process flow diagram of a method 300 for loading, coating, and unloading three batches of glass substrates 102 to build an electro-optical stack 104 on each batch of glass substrates 102. In a first step 301 of the method 300, a first batch A of glass substrates is positioned in the load lock (LL). In a second step 302, the first batch A is transferred into the first chamber (P1) for deposition of an index matching coating (IM). During that coating deposition of the first batch A, a second batch B of glass substrates is positioned in the load lock (LL) in a third step 303. After completion of the IM coating initiated in step 302, the first batch A is transferred to the second chamber (P2) for application of a transparent conductive oxide (TCO) coating in a fourth step 304. During that time, the second batch B is loaded into the first chamber (P1) for deposition of an IM coating in a fifth step 305. While the first batch A and the second batch B are undergoing coating processes, a third batch C of glass substrates is positioned in the load lock (LL) in a sixth step 306.

When the coating is finished for the first batch A, in a seventh step 307, the first batch A is moved from the second chamber (P2) to the buffer chamber (BUFF). Upon completion of the coating of the second batch B in the first chamber (P1), the second batch B is moved to the second chamber (P2) for deposition of a TCO coating in an eighth step 308. In a ninth step 309, the first batch A is moved from the buffer chamber (BUFF) to the first chamber (P1) for deposition of an antireflective (AR) coating. In the embodiment of the method 300 depicted in FIG. 5, the application of the AR coating to the first batch A is the final coating step, and thus, in a tenth step 310, the first batch A is transferred to the unload lock (UL) for removal from the system.

In an eleventh step 311, the third batch C is transferred from the load lock (LL) to the first chamber (P1) for deposition of an IM coating. After the third batch C is positioned in the first chamber (P1), the second batch B is transferred from the second chamber (P2) to the buffer chamber (BUFF) in a twelfth step 312. After completion of the deposition process for the third batch C, the third batch C is transferred from the first chamber (P1) to the second chamber (P2) for application of a TCO coating in a thirteenth step 313. In a fourteenth step 314, the second batch B is moved from the buffer chamber (Buff) to the first chamber (P1) for application of an AR coating. In a fifteenth step 315, the method 300 repeats processing steps as necessary to complete the coatings of the current batches and for application of coatings to new batch of substrates.

The method 300 illustrated in FIG. 5 is merely exemplary and designed to illustrate how multiple batches of substrates can be processed simultaneously without breaking vacuum by moving the batches between the first chamber, the second chamber, and the buffer chamber. In one or more other embodiments, a different number of coatings or different types of coatings may be applied to the substrates than in the illustrative embodiment of FIG. 5.

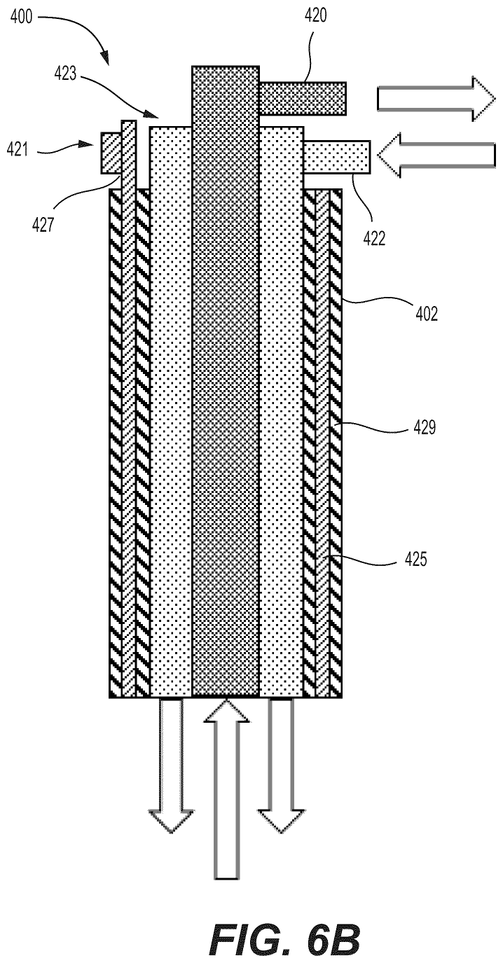

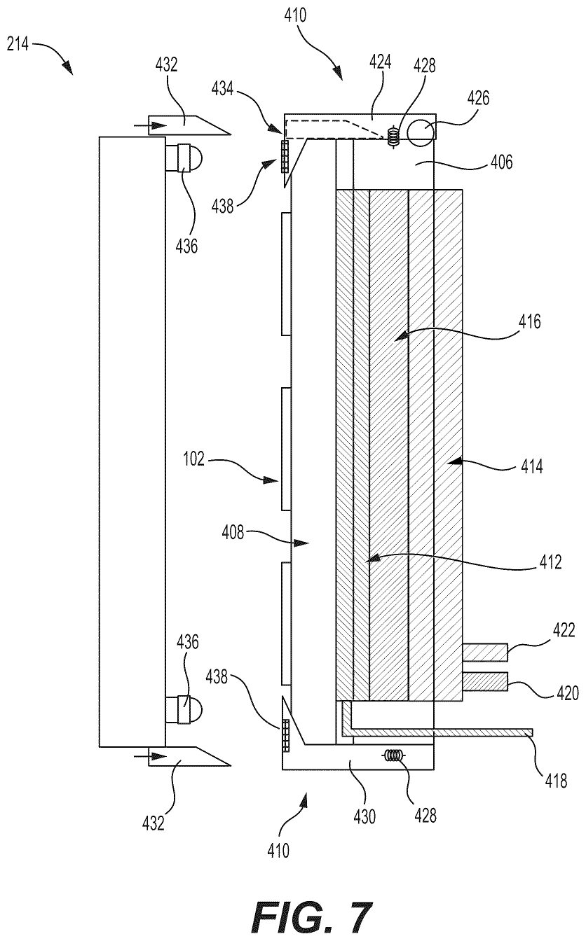

With reference now to FIGS. 6A, 6B, and 7, embodiments of the second rotating drum 252 (as shown in FIG. 4) are described in more detail. As mentioned above, the second rotating drum 252 may be biased with a DC voltage and thermally regulated to affect the conductive electrical coating deposition process. FIG. 6A depicts a section of a frame 400 defining a portion of the second rotating drum 252. In one or more embodiments, the frame 400 includes a central hub 402 having a plurality of arms 404 extending outwardly to a drum wall 406. In one or more embodiments, the glass substrates 102 (as can be seen in FIG. 7) are provided on a carrier 408 that is held by the drum wall 406; however, in one or more other embodiments, the glass substrate 102 may be held by the drum wall 406 (e.g., depending on the size of the glass substrate 102). In one or more embodiments, the carrier 408 is comprised of a steel or aluminum alloy. In one or more embodiments, the carrier 408 is held against the drum wall 406 with a clamp 410. In one or more embodiments, the carrier 408 is not held directly against the drum wall 406. For example, in one or more embodiments, the carrier 408 is in contact with an electrically conductive bias plate 412. Further, in one or more embodiments, a temperature regulating plate 414 is disposed on the drum wall 406 to heat or cool the carrier 408. However, the temperature regulating plate 414 is preferably electrically insulated from bias plate 412, and thus, in one or more embodiments, an isolator plate 416 is disposed between the temperature regulating plate 414 and the bias plate 412. In one or more embodiments, the isolator plate 416 is selected to be thermally conductive but electrically insulating. Examples of suitable materials for the isolator plate 416 include alumina (Al₂O₃) and mica, amongst other possibilities.

In one or more embodiments, the arms 404 of the frame 400 carry electrical connections 418 to provide current to the bias plate 412 and supply and return lines 420, 422 for refrigerant flow to the thermal regulating plate 414. As can be seen in FIG. 6A, the electrical connections 418 and supply and return lines 420, 422 radiate out from the central hub 402. The central hub 402 defines an axis of rotation for the frame 400 of the second rotating drum 252. In one or more embodiments, the central hub 402 provides specialized electrical and fluid connections. In one or more embodiments, the electrical connections 418 are established using segmented connectors 421. Further, in one or more embodiments, the central hub 402 includes a dual flow rotary union 423 in which one of the supply flow or the return flow flows through a center flow line of the hub 402 and the other of the supply or return flow flows through an outer annulus flow line around the center line.

FIG. 6B depicts a partial cross-sectional view along the axis of the central hub 402. The segmented connectors 421 include a cylindrical conductor 425 with segments removed to allow the supply and return lines 420, 422 to pass around or between the segmented connectors 421. In one or more embodiments, posts 425 extend upwardly from the cylindrical conductor 425 for connecting to electrical connections 418 across the arm 404 with the bias plate 412. Further, as shown in FIG. 6B, electrical contact between the cylindrical conductor 425 and the rotary union 423 for refrigerant flow is prevented by insulating material 429 that surrounds the cylindrical conductor 425. In one or more other embodiments, the supply and return lines 420, 422 can be positioned vertically along the central hub 402 in such a manner that the connections 421 to the bias plate 412 are located below the supply and return lines 420, 422.

FIG. 7 provides a more detailed view of a segment of the drum wall 406. As can be seen, the glass substrates 102 are attached to the carrier 408, which is provided in a stack with the bias plate 412, isolator plate 416, and thermal regulating plate 414. The plates 412, 414, 416 are mounted on the drum wall 406, and the carrier 408 is held in contact with the bias plate 412 with clamps 410. In one or more embodiments, the clamps 410 are spring loaded hinge clamps 424. As shown in one portion of FIG. 7, the hinge clamp 424 is rotatably connected to the drum wall 406 with a hinge joint 426 and biased in a closed position with a spring connection 428. In one or more embodiments, the clamps 410 are sliding clamps 430 configured to slide laterally in a direction perpendicular to the drum wall 406. As shown in another portion of FIG. 7, the sliding clamps 430 are also spring biased in a closed position with a spring connection 428.

To facilitate placement and removal of the carrier 408 from the drum wall 406, the at least one transfer robot 214 may include actuation plungers 432 configured to engage the clamps 410 holding the carrier 408 against the drum wall 406. In particular, the actuation plungers 432 can cause outward rotation of the hinge clamp 424 or lateral translation of the sliding clamp 430 to release the carrier 408. As shown in FIG. 7, the clamps 410 may include a channel 434 configured to receive the actuation plunger 432 to initiate disengagement of the clamp 410 from the carrier 408.

Further, in one or more embodiments, the at least one transfer robot 214 may position itself relative to the drum wall 406 based optical markings corresponding to the location of the clamps 410. As shown in FIG. 7, the at least one transfer robot 214 includes a positioning sensor 436 configured to recognize a cooperating element 438 to provide alignment between the actuation plungers 432 and the clamps 410. For example, the positioning sensor 436 may be an optical sensor (such as a laser or camera) that recognizes a cooperating element 438 in the form of a reflective or visual landmark.

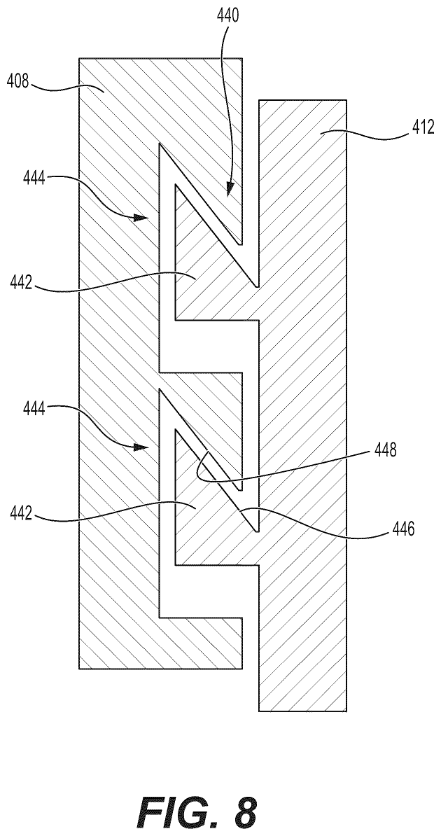

Besides clamps 410, the carrier 408 may be connected to the drum wall 406 in a variety of other ways. In one embodiment shown in FIG. 8, the carrier 408 is connected to the bias plate 412 via an interlocking arrangement 440, such as a tongue 442 and groove 444 arrangement. In the embodiment depicted, the bias plate 412 includes an outwardly extending tongue 442, and the carrier 408 has an inwardly extending groove 444. In one or more other embodiments, the tongue 442 and groove 444 can instead be formed on carrier 408 and the bias plate 412, respectively. Further, as shown in FIG. 8, the tongue 442 includes an upwardly extending angled surface 446 configured to engage a downwardly extending angled surface 448 of the groove 444. In this way, the angled surfaces 446, 448 frictionally engage each other under the influence of gravity. This enhanced degree of contact also ensures good electrical connection between the bias plate 412 and the carrier 408. In order for the at least one transfer robot 214 to place the carrier 408 on the bias plate 412, the at least one transfer robot 214 presses the carrier 408 towards or against the bias plate 412 such that the tongue 442 enters the groove 444, and then the at least one transfer robot 214 moves the carrier 408 downwardly to engage the angled surfaces 446, 448 before releasing the carrier 408.

Regardless of the particular manner by which the carrier 408 is attached to the drum wall 406 (e.g., whether by clamp 410 or interlocking arrangement 440), the carrier 408 should be able to withstand the centrifugal force of the rotating drum 252. In one or more embodiments, the centrifugal force F_{C} of the rotating drum is given by F_{C}=mω²r, in which m is the mass of the carrier 408, ω is the angular velocity of the drum 252, and r is the radial distance of the carrier 408 from the axis of rotation. In one or more embodiments, the force F (e.g., clamping force or frictional force) holding the carrier 408 to the rotating drum 252 is at least twice the centrifugal force F_{C}, i.e., F≥2F_{C}.

While the foregoing discussion considered the second rotating drum 252, the manner of clamping or holding a carrier 408 onto the drum frame 400 applies as well to the first rotating drum 226.

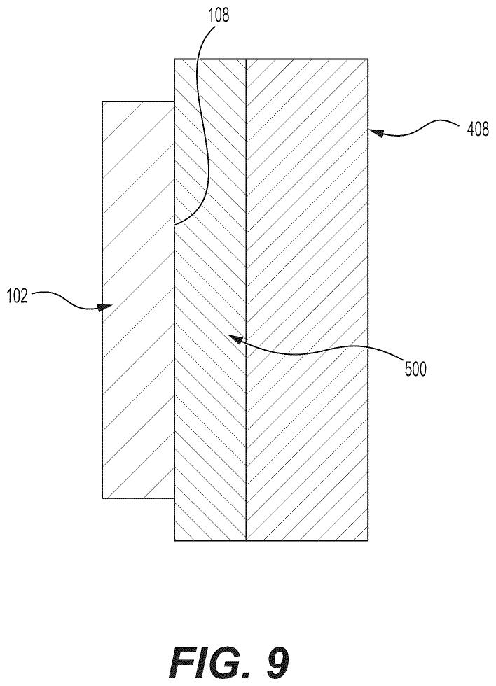

FIGS. 9-13 depict various structures for holding a glass substrate 102 to a carrier 408 during deposition of the electro-optical stack 104. FIG. 9 depicts a first embodiment for attaching glass substrates 102 to a carrier 408. As shown there, double-sided tape 500 adheres the second major surface 108 of the glass substrate 102 to the surface of the carrier 408.

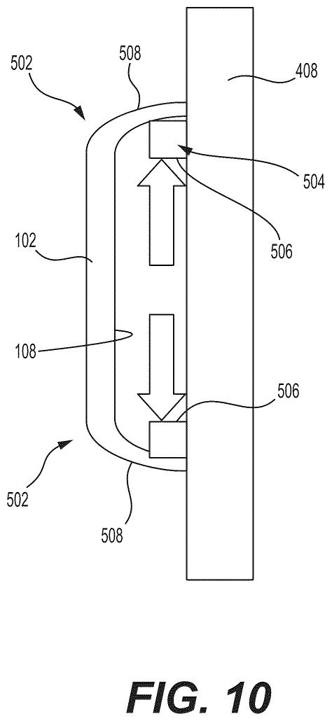

In some instances, the glass substrate 102 may not be planar. That is, as shown in FIG. 10, the glass substrate 102 may have undergone a forming operation to introduce one or more curvatures 502 to the glass substrate 102. In one or more such embodiments, the glass substrate 102 may be held to the carrier 408 using an expansion clamp 504. In the embodiment shown in FIG. 10, the expansion clamp 504 includes two posts 506 that are biased to expand away from each other. In this way, the posts 506 contact opposing edges 508 of the glass substrate 102 to frictionally engage the second major surface 108 of the glass substrate 102 in the region of the opposing edges 508 to hold the glass substrate 102.

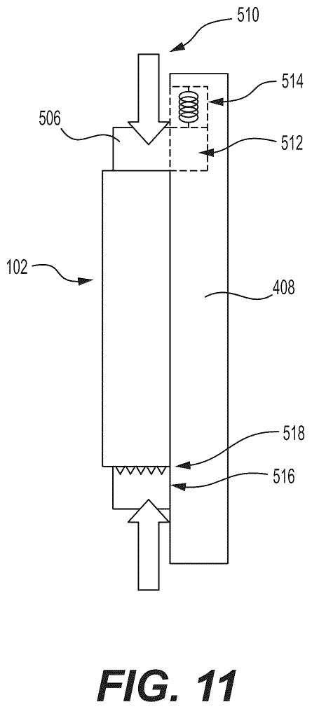

In another embodiment shown in FIG. 11, the carrier 408 includes a spring-biased recessed clamp 510. As can be seen, the recessed clamp 510 includes a clamp post 506 recessed into a channel 512 of the carrier 408. The post 506 is biased with a compression spring 514 to press against the minor surface 110 of the glass substrate 102. In one or more embodiments, an opposing peripheral edge of the glass substrate 102 can be contacted by another spring-biased recessed clamp 510. However, in one or more other embodiments, the spring-biased recessed clamp 510 can squeeze the glass substrate 102 against a stationary post 516 that extends from the surface of the carrier 408. In one or more embodiments, the stationary post 516 includes a surface texture, such as a knurled surface 518, to facilitate gripping of the glass substrate 102. Advantageously, the spring-biasing of the recessed clamp 510 allows for the clamp 510 to accommodate thermal expansion and contraction of the glass substrate 102 during deposition. Further, in one or more embodiments, the posts 506, 516 may be made of a high-temperature stable material that will not damage the glass substrate 102 during deposition, such as polyether ether ketone (PEEK) or acetal (e.g., Delrin® available from Delrin USA, LLC, Wilmington, DE).

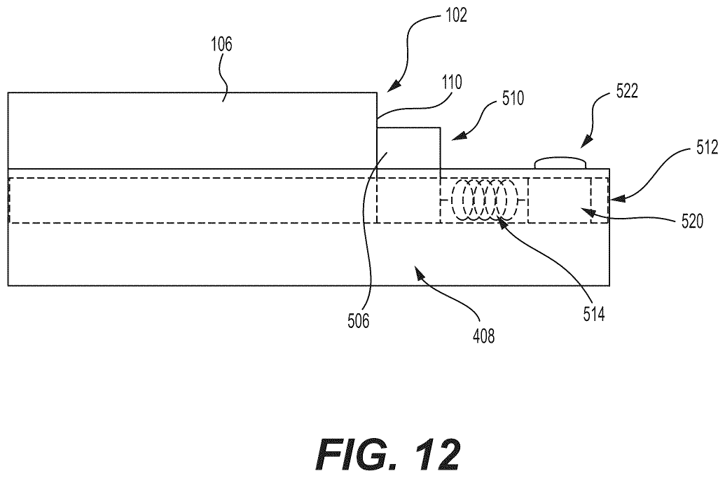

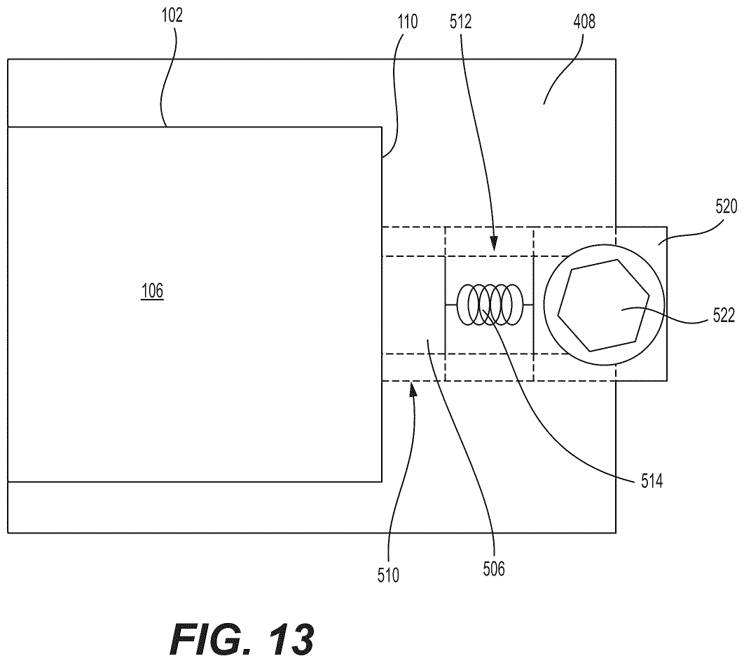

FIGS. 12 and 13 depict another embodiment of a recessed clamp configured to accommodate glass substrates 102 of substantially any size that fit onto the carrier 408. As can be seen in FIG. 12, the recessed clamp 510 is movable within the channel 512. The recessed clamp 510 includes a spring stop 520 that slides within the channel 512 and is locked into place with a fastener 522. The compression spring 514 is attached at one end to the spring stop 520 and to the post 506 at the other end. In this way, the recessed clamp 510 can be slid back and forth within the channel 512 to engage the minor surface 110 of the glass substrate 102.

Advantageously, each of the attachment mechanisms described in relation to FIGS. 9-13 allows for deposition of a coating on the entire first major surface 106 of the glass substrate 102 without damaging the glass substrate 102 during deposition.

The embodiments of the system and method for applying an electro-optical coating stack 104 to glass substrates 102 disclosed herein provide several advantages over conventional deposition systems and methods. In particular, the deposition process is streamlined for faster processing of complex electro-optical stacks 104, in particular by allowing for parallel processing of batches of glass substrates 102 in the same equipment. Further, enhanced control over the properties of each coating layer is provided because, by not breaking vacuum between application of coating layers, contamination between layers is substantially reduced or eliminated. The system provides a “clean” chamber desirable for application of nonconductive optical coatings 112 that is isolated from the “dirty” chamber for application of the conductive electrical coatings 114. Despite the isolation of the chambers for optical and electrical coatings, each chamber can be optimized for its respective coating without breaking vacuum when moving between the optical and electrical chambers.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more than one component or element and is not intended to be construed as meaning only one.

It will be apparent to those skilled in the art that various modifications and variations can be made without departing from the spirit or scope of the disclosed embodiments. Since modifications, combinations, sub-combinations and variations of the disclosed embodiments incorporating the spirit and substance of the embodiments may occur to persons skilled in the art, the disclosed embodiments should be construed to include everything within the scope of the appended claims and their equivalents.

What is claimed is:

1. A system for depositing coatings on a plurality of substrates, comprising:
a first chamber comprising a plurality of first deposition modules arranged around a first perimeter of the first chamber, the plurality of first deposition modules configured to deposit nonconductive coatings on the plurality of substrates, the first perimeter of the first chamber defining a first interior;
a first rotating drum disposed in the first interior and configured to hold the plurality of substrates.
a second chamber comprising a plurality of second deposition modules arranged around a second perimeter of the second chamber, the second deposition modules configured to deposit conductive coatings on the plurality of substrates, and the second perimeter of the second chamber defining a second interior;
a second rotating drum disposed in the second interior and configured to hold the plurality of substrates; and
a transfer chamber disposed between the first chamber and the second chamber, the transfer chamber comprising at least one transfer robot configured to transfer substrates between the first rotating drum and the second rotating drum; and
wherein the first chamber, the transfer chamber, and the second chamber are connected such that the plurality of substrates can be transferred back and forth from the first chamber through the transfer chamber to the second chamber without breaking vacuum.

2. The system of claim 1, wherein at least one of the first rotating drum or the second rotating drum is electrically biased.

3. The system of claim 1, wherein the plurality of first deposition modules comprises sputtering modules configured to deposit metal ions on the plurality of substrates.

4. The system of claim 1, wherein the plurality of second deposition modules comprises sputtering modules configured to deposit metal ions on the plurality of substrates.

5. The system of claim 1, wherein the second deposition chamber further comprises a heating module.

6. The system of claim 1, wherein the second rotating drum comprises a frame comprising bias plates configured to provide DC bias for the plurality of second deposition modules during the deposition of the conductive coatings.

7. The system of claim 6, wherein the frame further comprises a thermal regulation system configured to regulate a temperature of the plurality of substrates during deposition of the conductive coatings.

8. The system of claim 7, wherein the frame further comprises isolator plates disposed between the bias plates and the thermal regulation system, the isolator plates configured to electrically insulate the thermal regulation system from the bias plates.

9. The system of claim 7, wherein the frame comprises a central hub with a plurality of arms radially extending from the central hub to a drum wall.

10. The system of claim 1, wherein the first rotating drum and the second rotating drum each comprise a plurality of spring clamps configured to hold the plurality of substrates or to hold carriers for the plurality of substrates; and
wherein the at least one transfer robot comprises plunger actuators configured to disengage the plurality of spring clamps to release the plurality of substrates or carriers for the plurality of substrates so that the at least one transfer robot is able to transfer the plurality of substrates or carriers between the first rotating drum and the second rotating drum.

11. The system of claim 10, wherein the at least one transfer robot comprises a clamp sensor configured to detect proximity to the plurality of spring clamps.

12. The system of claim 10, wherein the plurality of spring clamps are each configured to apply a clamping force to the plurality of substrates or to the carriers for the plurality of substrates, the first rotating drum and the second rotating drum are configured to impart a centrifugal force on the plurality of substrates or on the carriers during rotation, and the clamping force is at least twice the centrifugal force.

13. The system of claim 1, further comprising a buffer chamber connected to the transfer chamber, the buffer chamber providing storage for substrates of the plurality of substrates during transfer of the substrates between the first deposition chamber and the second deposition chamber without breaking vacuum.

14. A method of applying coatings to a plurality of substrate batches, comprising:
loading a first substrate batch onto a first rotating drum configured to rotate within a first chamber;
depositing, under vacuum, a first coating on the first substrate batch using a plurality of first deposition modules, and the first coating is one of a nonconductive optical coating or a conductive electrical coating;
transferring the first substrate batch from the first chamber through a transfer chamber into a second chamber;
loading the first substrate batch onto a second rotating drum configured to rotate within the second chamber;
depositing, under vacuum, a second coating on the first substrate batch, using a plurality of second deposition modules, and the second coating is the other of the nonconductive optical coating or the conductive electrical coating;
wherein the first coating and the second coating are deposited without breaking vacuum during transferring from the first chamber through the transfer chamber and into the second chamber.

15. The method of claim 14, wherein, during depositing of the second coating, the method further comprises loading a second substrate batch onto the first rotating drum and depositing, under vacuum, the first coating on the second substrate batch.

16. The method of claim 14, wherein, during depositing of the conductive electrical coating, the method further comprises annealing the conductive electrical coating.

17. The method of claim 14, wherein, during depositing of the conductive electrical coating, the method further comprises cooling the respective first rotating drum or the second rotating drum in the first chamber or the second chamber in which the conductive electrical coating is deposited.

18. The method of claim 14, wherein, after depositing the conductive electrical coating, the method further comprises cooling the respective first rotating drum or the second rotating drum in the first chamber or the second chamber in which the conductive electrical coating is deposited.

19. The method of claim 14, wherein, during the depositing the first coating and the second coating, the method further comprises electrically biasing the first rotating drum and the second rotating drum.

20. The method of claim 14, wherein the first substrate batch is provided on one or more carriers;
the loading the first substrate batch onto the first rotating drum further comprises holding the one or more carriers between spring clamps; and
the transferring the first substrate batch further comprises disengaging the spring clamps using actuator plungers disposed on at least one robot arm positioned in the transfer chamber and grasping the one or more carriers with the at least one robot arm.
